(19) United States
(12) Patent Application Publication
(10) Pub. No.: US 2011/0068342 A1
(43) Pub. Date: Mar. 24, 2011

(54) Laser Process for Minimizing Variations in Transistor Threshold Voltages

(76) Inventors: Themistokles Afentakis, Vancouver, WA (US); Robert S. Sposili, Vancouver, WA (US); Steven R. Droes, Camas, WA (US)

(21) Appl. No.: 12/563,059

(22) Filed: Sep. 18, 2009

(51) Int. Cl. H01L 29/786; H01L 21/20; H01L 29/04

(52) U.S. Cl. 257/66; 438/487; 257/75; 257/E21.134; 257/E29.003; 257/E29.292

(57) ABSTRACT

A laser method is provided for minimizing variations in transistor threshold voltages. The method supplies a wafer with a laser-crystallized active semiconductor film having a top surface with a first surface roughness. The method laser anneals the active semiconductor film, and in response to the laser annealing, melts the top surface of the active semiconductor film. The result is a top surface with a second roughness, less than the first roughness. More explicitly, the wafer active semiconductor film is crystallized using a laser with a first fluence, and then laser annealed with a second fluence, less than the first fluence. As compared with complementary metal-oxide-semiconductor field-effect (CMOSFET) thin-film transistor (TFT) structures formed in unprocessed regions of the active semiconductor film, the TFT threshold voltage standard deviation for TFTs in laser annealed portions of the active film are 60% less for n-channel and 30% less for p-channel TFTs.

### BACKGROUND OF THE INVENTION

1. Field of the Invention

This invention generally relates to integrated circuit (IC) fabrication and, more particularly, to a laser process for smoothing semiconductor surfaces and minimizing variations in the threshold voltages of adjoining transistor devices fabricated in the smoothed surface.

2. Description of the Related Art

Polycrystalline silicon (polysilicon) thin-film transistors (TFT) are the semiconductor device of choice, for use in high performance circuitry fabricated on limited-thermal budget, substrates. Typically, the TFTs are fabricated on glass, but they are also used in flexible electronics fabricated on polymer or metal foil substrates, for use in applications such as flat-panel displays and radio frequency identification (RFXD) tags, to name a few examples.

For all applications that require linear circuits (i.e. the circuit output voltage or current is proportional to an input current or voltage signal), it is important to minimize the non-uniformities in the TFT ON characteristics, such as threshold voltage V_{TH}, effective mobility μ_{eff}, and to a lesser degree, the channel length modulation parameter λ. Threshold voltage uniformity is also important in non-linear (digital ON-OFF switching) transistor systems, such as active matrix displays, including active-matrix liquid crystal, display (LCD) and organic light-emitting diode (OLED) systems. In the case of display systems in particular, TFT V_{TH} and mobility non-uniformities in adjacent pixels are detrimental to the picture quality, and they have to be corrected either with software algorithms or with more complex pixel architectures (three or more TFTs per pixel) designed to reject non-uniformities, in particular relating to V_{TH}.

It would be advantageous if non-uniformities in the electrical characteristics of TFTs, fabricated in adjacent regions of an active semiconductor film, could be minimized without the addition for costly processing steps.

### SUMMARY OF THE INVENTION

Described herein is a laser process for the fabrication of complementary TFT architectures (N-channel and P-channel MOSFETs) with a very tight range in V_{TH} distribution, as compared to conventional devices. The TFT process flow involves laser irradiation of crystallized active Si film crystallization, making the fabricated TFTs high-performance devices with a high effective mobility. Test results indicate an improvement by a factor of 2 in V_{TH} uniformity for TFTs crystallized with a continuous-wave (CW) laser. However, the process is not limited to any particular type of laser.

For example, an excimer laser annealing step is performed on top-gate self-aligned NMOS and PMOS TFTs after the crystallization of the active Si film. The laser process may be performed on as-deposited polyerystalline or amorphous semiconductor films that have been laser re-crystallized. In additional to the improvement in V_{TH} uniformity, one more advantage of the laser process is a reduction in surface roughness.

Although the effective mobility of the laser processed device is not significantly improved, indicating that the carrier surface scattering properties of the film are not significantly improved, a considerable improvement in threshold voltage uniformity is achieved. It is believed, that the physical mechanism for improving We uniformity involves defect passivation in the TFT channel area and improving the semiconductor/gate dielectric interface.

Accordingly, a laser method is provided for minimizing variations in transistor threshold voltages. The method supplies a wafer with a laser-crystallized active semiconductor film having a top surface with a first, surface roughness. The method laser anneals the active semiconductor film, and in response to the laser annealing, melts the top surface of the active semiconductor film. The result is a top surface with a second roughness, less than the first roughness. More explicitly, the wafer active semiconductor film is crystallized using a laser with a first fluence, and then laser annealed with a second fluence, less than the first fluence.

As compared with complementary metal-oxide-semiconductor field-effect (CMOSFET) thin-film transistor (TFT) structures formed in unprocessed regions of the active semiconductor film, the TFT threshold voltage standard deviation for TFTs in laser annealed (smoothed) portions of the active film, are 60% less for n-channel and 30% less for p-channel TFTs. Other benefits of the laser annealing process are a reduction in active semiconductor sheet resistance and interface trap density.

Additional details of the above-described method, a laser-smoothed active semiconductor film wafer, and CMOSFET TFT array are provided below.

### BRIEF DESCRIPTION OF THE DRAWINGS

FIG. 1 is a partial cross-sectional view of a laser-smoothed active semiconductor film, wafer.

FIG. 2 is a partial cross-sectional view of a complementary metal-oxide-semiconductor field-effect (CMOSFET) thin-film transistor (TFT) array.

FIG. 3 is a plan view of continuous wave (CW)-crystallized wafer with a 100 nanometer (nm) precursor Si film.

FIG. 4 is a graph of RMS surface roughness of irradiated samples vs. laser fluence.

FIG. 5 is a graph of irradiated sample sheet resistance vs. laser fluence.

FIG. 6 depicts cross-sectional views of steps in the laser surface treatment process.

FIGS. 7A and 7B are graphs of V_{TH} vs. mobility for NMOS devices processed with standard and laser surface treatment process flows, respectively.

FIG. 8 is a flowchart illustrating a laser method for minimizing variations in transistor threshold voltages.

### DETAILED DESCRIPTION

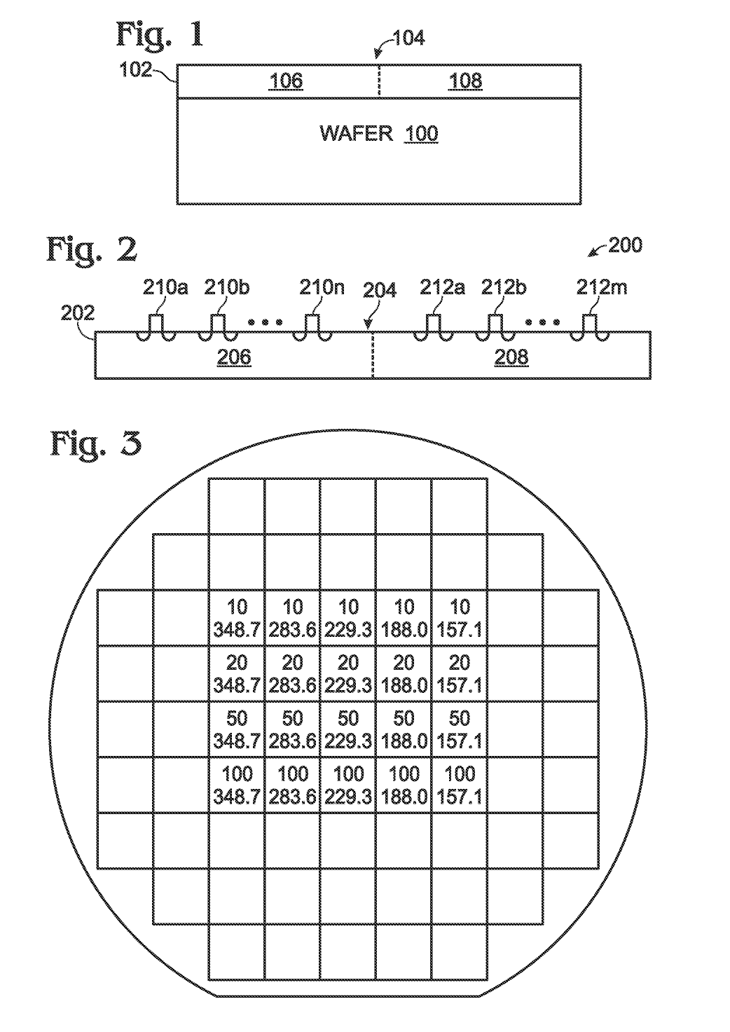

FIG. 1 is a partial cross-sectional view of a laser-smoothed active semiconductor film wafer. The wafer 100 comprises a laser-crystallized active semiconductor film 102 having a top surface 104 with a laser-smoothed first portion 106 and a non-laser-smoothed second portion 108. The semiconductor film 102 is typically silicon (Si), germanium (Ge) or a blend of Si and Ge (SiGe), although other conventional semiconductor materials with similar properties may also be used. The first portion top surface 106 has a first sheet resistance, and the second portion top surface 108 has a second sheet resistance, greater than the first sheet resistance. Further, the first portion top surface 106 has a first interface trap density, and the second portion top surface 108 has a second interface trap density, greater than the first interface trap density. Note: as explained in more detail below, the interface trap density is typically measured after devices are fabricated on the active film 102

FIG. 2 is a partial cross-sectional view of a complementary metal-oxide-semiconductor field-effect (CMOSFET) thin-film transistor (TFT) array. The array 200 comprises a laser-crystallized active semiconductor film 202 having a top surface 204 with a laser-smoothed first portion 206 and a non-laser-smoothed second portion 208. A first group of TFTs, e.g., TFTs 210a through 210n, are formed in the first portion top surface 206. A second group of TFTs, e.g., 212a through 21.2m, are formed in a second portion top surface 208. Variables n and m are not limited to any particular value. The TFT threshold voltage standard deviation for TFTs 210 in the first portion 206 is less for the TFTs 212 in the second portion 208. The standard deviation for first portion TFTs 210 is 60% for n-channel TFTs, and 30% for p-channel TFTs. The laser-crystallized active semiconductor film 202 is typically Si, Ge, or SiGe.

### Functional Description

Initial Experiment: Selecting the Excimer Laser Surface-Treatment Conditions

FIG. 3 is a plan view of continuous wave (CW)-crystallized wafer with a 100 nanometer (nm) precursor Si film. The numbers indicate number of shots (from 10 to 100) and laser beam energy density (fluence, in mJ/cm²) of the applied laser smoothing process. Table 1 lists RMS surface roughness Ra for irradiated samples. As received, the CW crystallized film (prior to smoothing irradiation) showed Ra=21.27 nm.

TABLE 1

| | Ra (nm) | | | |
|---|---|---|---|---|
| Fluence (mJ/cm²) | Shots = 10 | Shots = 20 | Shots = 50 | Shots = 100 |
| 348.7 | 24.13 | 22.87 | 37.83 | 90.83 |
| 283.6 | 17.39 | 20.65 | 33.51 | 67.55 |
| 229.3 | 19.17 | 21.89 | 20.36 | 21.1 |
| 188.0 | 15.83 | 19.07 | 25.18 | 18.53 |
| 157.1 | 20.88 | 22.29 | 20.53 | 18.31 |

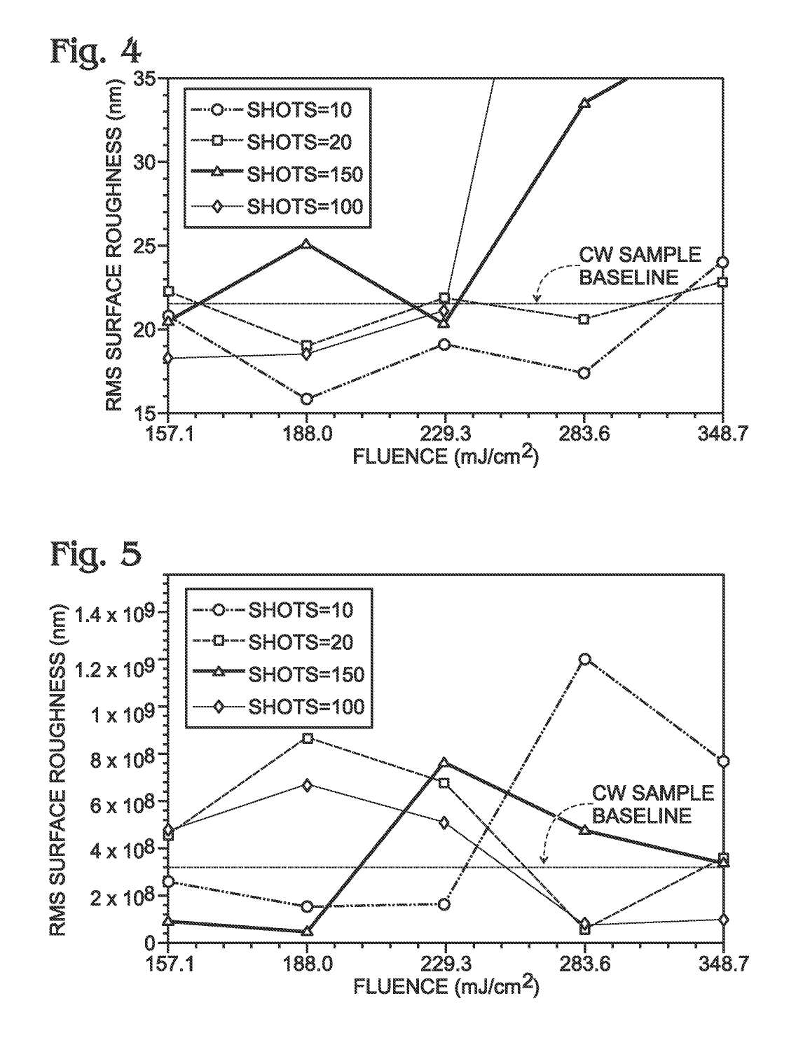

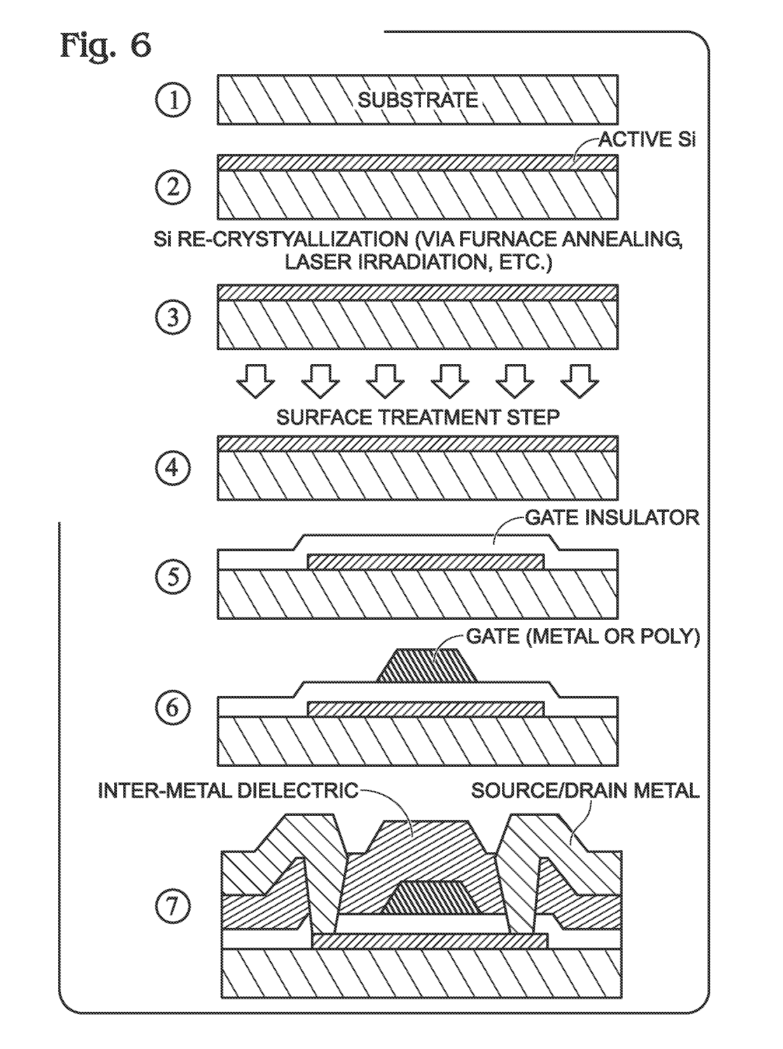

FIG. 4 is a graph of RMS surface roughness of irradiated samples vs. laser fluence. The best overall improvement is obtained from, the sample with 10 shots, and a fluence of 188 mJ/cm².

FIG. 5 is a graph of irradiated sample sheet resistance vs. laser fluence. The plot also indicates the sheet resistance Rs(Ω/square) of the as-crystallized CW sample prior to smoothing.

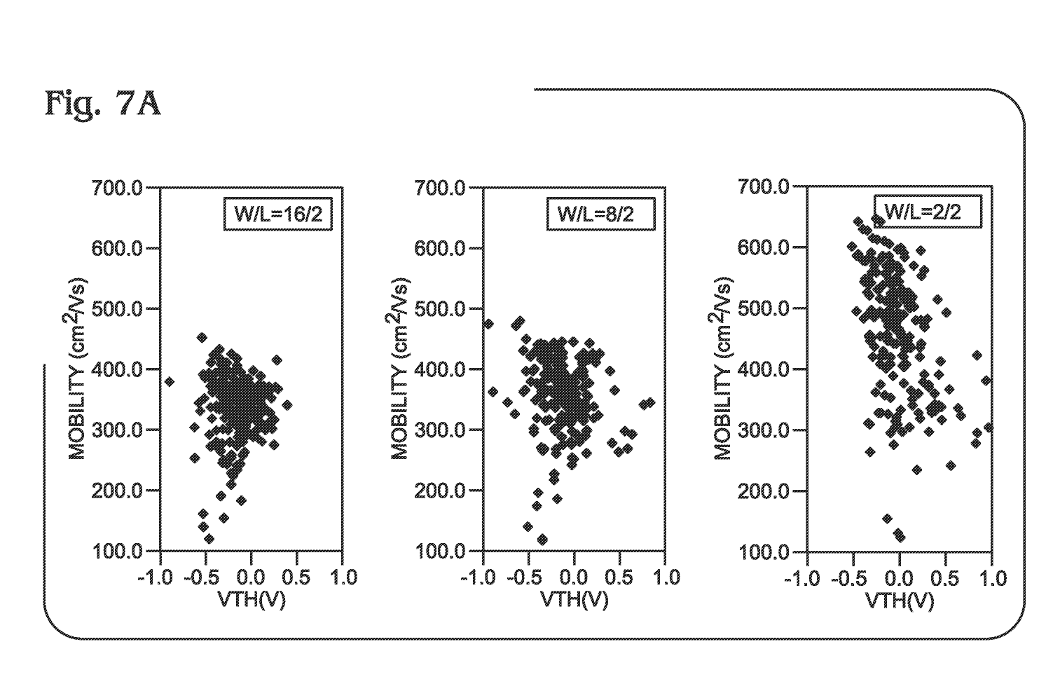

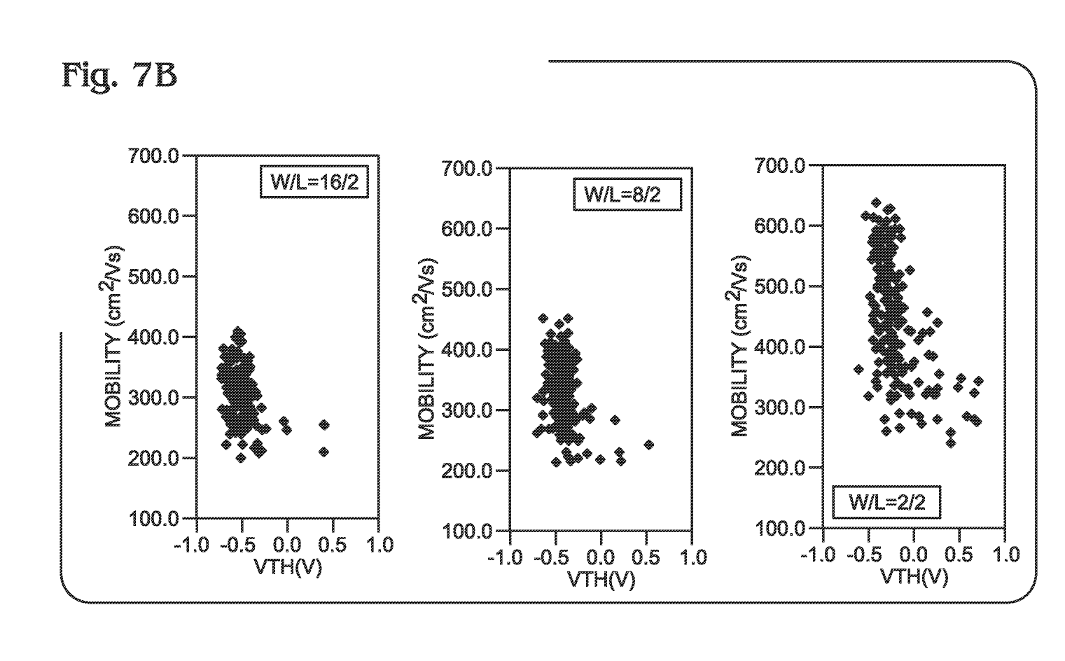

Based on the results of FIG. 4 and Table 1, the condition selected for excimer laser surface treatment was 10 shots, and a fluence of 188 mJ/cm². According to FIG. 5, there is also significant sheet resistance improvement for this condition (as well as for other conditions, e.g., 50 shots at 188 mJ/cm² and 20/100 shots at 283.6 mJ/cm²). This result points to an improvement in the film's electrical transport properties, probably due to partial melting and re-crystallization of the surface. Thus, a sheet resistance plot, such as FIG. 5, may be more suitable in selecting the optimal excimer laser surface treatment conditions than a surface roughness plot. As shown in FIGS. 7A and 7B, the development of a process to smooth the active film surface led to unexpected consequences. That is, the laser surface treatment originally intended to promote surface smoothness led to an unforeseen improvement in narrowing the threshold voltage range of adjacent devices. Adjacent devices with very similar threshold voltages promote improved circuit performance, especially if the devices are intended to operate in a linear range.

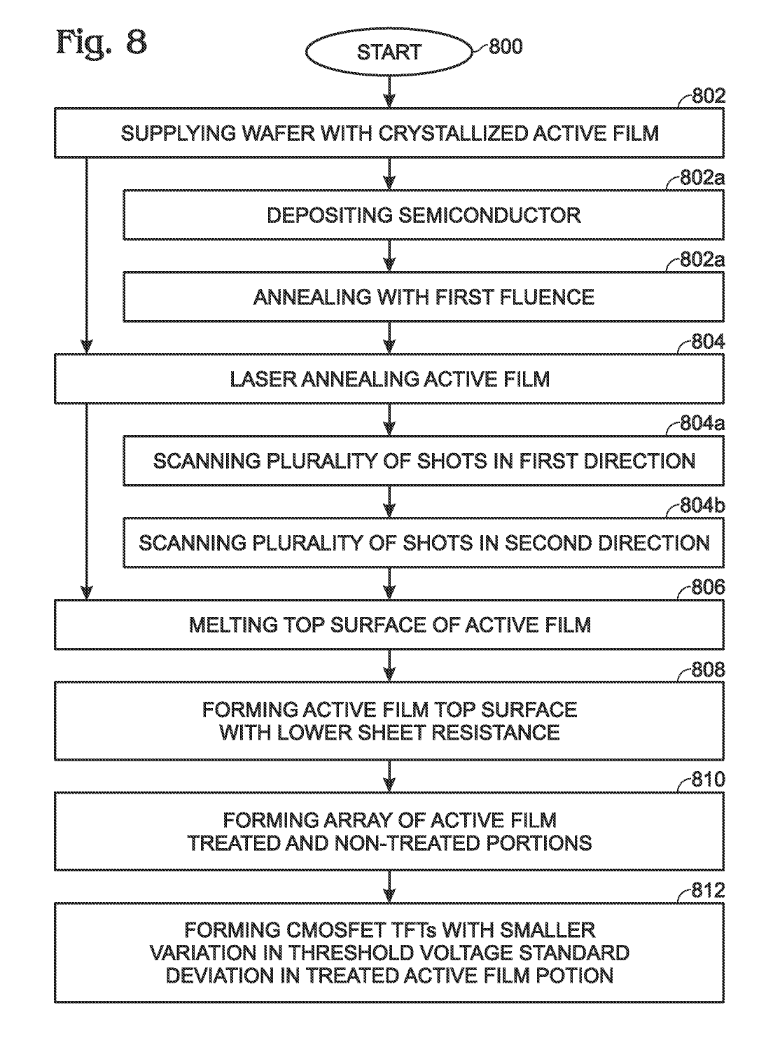

FIG. 8 depicts cross-sectional views of steps in the laser surface treatment process. Generally, the excimer laser surface treatment step is performed after active Si deposition and (re)crystallization, prior to active film patterning. The process begins with a properly base-coated substrate (Step 1), onto which the amorphous or polycrystalline active semiconductor film is deposited (Step 2). In Step 3, this active film is (re)crystallized with a suitable process (furnace anneal, laser or other process). This step might not be necessary if the active film is polycrystalline (with an adequate crystallinity for the intended application) as-deposited in Step 2.

Step 4 involves the surface treatment of the active film with excimer laser irradiation, as described in more detail below. Next, the gate insulator is deposited or grown—typically silicon dioxide or silicon nitride (or a stack of these films—Step 5). In Step 6 the gate electrode is deposited and patterned, and in Step 7 the inter-layer dielectric is deposited, vias are cut, and the top metal layer is deposited and patterned, making contact with the active and gate films through the vias. Additional passivation steps are not shown in the interest of brevity.

### Experimental Results

Devices fabricated by the above-described process were compared against devices made in an identical top-gate self-aligned TFT fabrication flow without the surface treatment excimer laser step. A large improvement in V_{TH} distribution for both n-channel and p-channel TFTs was noted, as shown by the data in Tables 2 & 3. No substantial improvement in subthreshold slope or mobility was achieved.

TABLE 2
Electrical characteristics of standard processing flow TFTs

| | PMOS W/L = 8/1.3 | | | NMOS W/L = 8/1.3 | | |
|---|---|---|---|---|---|---|
| | VT (V) | S (mV/dec) | Mob (cm²/Vs) | VT (V) | S (mV/dec) | Mob (cm²/Vs) |
| Mean | −0.896 | 141 | 118.93 | −0.182 | 198 | 427.44 |
| St. Dev. | 0.215 | 27 | 16.74 | 0.194 | 78 | 58.01 |
| Max | −0.356 | 289 | 149.95 | 0.236 | 574 | 526.77 |
| Min | −1.331 | 115 | 63.82 | −0.547 | 122 | 182.77 |

TABLE 3
Electrical characteristic of TFTs processed with laser surface treatment

| | PMOS W/L = 8/1.3 | | | NMOS W/L = 8/1.3 | | |
|---|---|---|---|---|---|---|
| | VT (V) | S (mV/dec) | Mob (cm²/Vs) | VT (V) | S (mV/dec) | Mob (cm²/Vs) |
| Mean | −1.339 | 136 | 108.39 | −0.547 | 245 | 458.04 |
| St. Dev. | 0.149 | 15 | 17.31 | 0.088 | 108 | 68.48 |
| Max | −0.890 | 208 | 141.43 | −0.267 | 975 | 593.08 |
| Min | −1.692 | 116 | 41.30 | −0.743 | 153 | 210.98 |

FIGS. 7 Å and 7B are graphs of V_{TH} vs. mobility for NMOS devices processed with standard and laser surface treatment process flows, respectively. It can clearly been seen that the threshold range for the laser surface treated-devices is narrower than for the conventional devices.

The films in FIG. 7B were irradiated using a XeCl excimer laser (wavelength=308 nm). An optical system shaped the beam into a rectangular “flood” pattern 1 mm×10 mm. The system used projection optics (5× demagnification) to image the flood pattern from a photomask onto the film. However, other optical schemes can achieve an equivalent result. For the purpose of minimizing optical artifacts at the edges of the beam, the actual mask pattern was not a simple rectangular aperture; it included an array of sub-resolution features around the periphery to produce a more diffuse beam edge when imaged through the projection system.

The laser was fired, at a constant repetition rate of 200 Hz and at a constant pulse energy of 600 mJ. The fluence of the beam as imaged onto the film was modulated through the use of a dual-plate variable-angle dielectric attenuator. The attenuated fluence of the beam at the film plane was set to be approximately 210 mJ/cm². This fluence was selected as appropriate for inducing partial melting of the film based on evaluation of some test scans. The films were scanned (in the direction of the short axis of the beam) at a speed such that they moved a distance of 0.1 mm in between laser pulses (1,200 mm/min). Consequently, given, the short axis beam length of 1 mm, each point on the film was irradiated 10 times.

Upon conclusion of each individual scan, the film was translated the length of the long axis of the beam (10 mm) in the perpendicular direction and another scan was performed. This rastering was repeated until, the entire area of interest of the film was irradiated.

The NMOS TFT quality of the active silicon film and the active silicon/gate insulator interface quality were investigated by extracting the defect densities for the bulk and the Si/SiO₂ interface. This investigation was performed for both conventional and two-step surface treatment processes.

Defect densities were extracted by using the ON-current activation energy method, a variant of the field effect conductance method; I_{D}V_{G} characteristics were measured at V_{D}=100 mV, at temperatures ranging from 25 to 125° C. All devices studied were W/L=4 μm/2 μm. The bulk active Si defect density was characterized by the deep trap density, that is, by the density of defect sites located close to the middle of the forbidden energy gap. These defect sites have the greatest impact on the TFT threshold voltage and sub-threshold characteristics. For the interface state density, a uniform effect distribution across the entirety of the forbidden energy gap was assumed. Interface states also have a big impact on threshold and sub-threshold TFT characteristics. The results are shown below in Table 4.

The two-step laser surface treatment process results in an improvement in both bulk states and interface states. The improvement in bulk states is small, and for practical purposes, it is very close to the device-to-device variation of the defect extraction process. The minimal improvement of bulk defects with the proposed irradiation process is physically justified by the fact that the second, low-energy laser irradiation step only melts a small portion of the active Si film, estimated at about the top 30% of the active Si film thickness. As the molten portion solidifies, solid portions of the polyerystalline grains act as seeds, and the existing grain structure at the bulk recovers.

However, interface defect measurements indicate a substantial improvement in interface trap density, more than an order of magnitude. It is believed that the improved interface trap density is responsible for the observed improvement in Y_{TH} range.

TABLE 4
Bulk and interface trap densities of average mobility, V_{TH} devices

| | Bulk states | Interface states |
|---|---|---|
| | (eV⁻¹cm⁻⁸) | (eV⁻¹cm⁻²) |
| Sequential Interal solidification (SLS) | 6.5 × 10¹⁸ | 3.3 × 10¹⁶ |
| directional (conventional process) | | |
| SLS process (two-step surface treatment) | 3.9 × 10¹⁸ | 2.7 × 10¹⁴ |

Bulk trap density refers to the density of defects in the main body of the film (units: defects per unit volume). Interface trap density refers to the density of defects only on the exposed surface of the film (units: defects per unit area). When a gate dielectric is deposited on top of the film, the Si/SiO₂ interface trap density becomes an issue. Since the crystal terminates at the surface, there are many dangling bonds there, so interface trap density is usually high.

In the above-described laser surface treatment process, the bulk of the film is not completely melted. When the film solidifies, the solid bottom part acts as a seed. So the bulk of the solidified film has the same crystal structure (and similar bulk defect density) that it had prior to the laser surface treatment Only the surface defect density is substantially improved. However, trap densities can only be measured if the film is fabricated into some type, of device, such as a transistor or capacitor.

The threshold voltage of a MOSFET is usually defined as the gate voltage where an inversion layer forms at the interface between the insulating layer (oxide) and the substrate (body) of the transistor. For example, in an n-MOSFET the substrate of the transistor is composed of p-type silicon, which has positively charged mobile holes as carriers. When a positive voltage is applied on the gate, an electric field causes the holes to be repelled from the interface, creating a depletion region containing immobile negatively charged acceptor ions. A further increase in the gate voltage eventually causes electrons to appear at the interface, in what is called an inversion layer, or channel. The gate voltage at which the electron density at the interface is the same as the hole density in the neutral bulk material is called the threshold voltage. Practically, the threshold voltage is the voltage at which there are sufficient electrons in the inversion layer to make a low resistance conducting path between the MOSFET source and drain.

FIG. 8 is a flowchart illustrating a laser method for minimizing variations in transistor threshold voltages. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence, The method starts at Step 800.

Step 802 supplies a wafer with a laser-crystallized active semiconductor film having a top surface with a first surface roughness. Typically, the film is Si, Ge, or SiGe, Step 804 laser anneals the active semiconductor film. In response to the laser annealing. Step 806 melts (just) the top surface of the active semiconductor film. Step 808 forms a top surface with a second roughness, less than the first roughness. For example, supplying the wafer with a laser-crystallized active semiconductor film in Step 802 may include supplying an active semiconductor film with a first thickness, and melting the top surface of the active semiconductor film in response to the laser annealing (Step 806) includes melting about the top 30% of the active semiconductor film.

In one aspect, supplying the wafer with the laser-crystallized active semiconductor film in Step 802 includes supplying the wafer top surface having a first sheet resistance, and forming the top surface with the second roughness in Step 808 includes forming the top surface with a second sheet resistance, less than the first sheet resistance. In another aspect. Step 802 supplies a wafer top surface having a first interface trap density, and Step 808 forms a top surface with a second interface trap density, less than the first interface trap density.

In one aspect, supplying the wafer with the laser-crystallized active semiconductor film in Step 802 includes substeps. Step 802a deposits a semiconductor film on a wafer top surface. Step 802b crystallizes the semiconductor film using a laser with a first fluence. Then, laser annealing the active semiconductor film in Step 806 includes annealing with a second fluence, less than the first fluence.

In another aspect, laser annealing the active semiconductor film in Step 806 includes laser annealing a first portion of the active semiconductor film top surface, leaving a second portion of the active semiconductor film top surface unexposed to the laser annealing. Then, subsequent to forming the top surface with the second roughness in Step 808, Step 810 forms an array of active semiconductor film sections in the top surfaces of the active semiconductor film first and second portions. Step 812 forms a CMOSFET TFT structure in each active semiconductor film section, where the TFT threshold voltage standard deviation for TFTs in the first portion is less TFTs in the second portion, by 60% for n-channel and 30% for p-channel TFTs.

In one example, supplying the wafer with a laser-crystallized active semiconductor film in Step 802 includes supplying an active semiconductor film having a thickness of about 50 nanometers (nm). Then, laser annealing the active semiconductor film in Step 804 includes using a laser having: a wavelength of 308 nanometers (nm); a repetition rate of about 200 Hz; a total energy pulse energy of about 210 milliJoules per centimeter square (mJ/cm²); and, a beam shape of 1 mm×10 mm.

In one aspect, laser annealing the active semiconductor film includes substeps. Step 804a scans the active semiconductor film, with a plurality of laser shots in a first direction. Step 804b scans the active semiconductor film, with, a plurality of shots in a second direction, orthogonal to the first direction. In another aspect, Step 804a irradiates each point on the active semiconductor top surface with a first number of shots in a range of about 10 to 50. Step 804b irradiates each point on the active semiconductor top surface with the first number of shots.

A laser method for smoothing active film surfaces and minimizing variations in transistor threshold voltages has been provided. Examples of particular materials and processes steps have been given to illustrate the invention. However, the invention is not limited to just these examples. Other variations and embodiments of the invention, will occur to those skilled in the art.

We claim:

1. A laser method for minimizing variations in transistor threshold voltages, the method comprising;
supplying a wafer with a laser-crystallized active semiconductor film having a top surface with a first surface roughness;
laser annealing the active semiconductor film;
in response to the laser annealing, melting the top surface of the active semiconductor film; and,
forming the top surface with a second roughness, less than the first roughness.

2. The method of claim 1 wherein supplying the wafer with, the laser-crystallized active semiconductor film includes:
depositing a semiconductor film on a wafer top surface;
crystallizing the semiconductor film using a laser with a first fluence; and,
wherein laser annealing the active semiconductor film includes annealing with a second fluence, less than the first fluence.

3. The method of claim 1 wherein laser annealing the active semiconductor film includes laser annealing a first portion of the active semiconductor film top surface, leaving a second portion of the active semiconductor film top surface unexposed to the laser annealing;
the method further comprising:
subsequent to forming the top surface with the second roughness, forming an array of active semiconductor film sections in the top surfaces of the active semiconductor film first and second portions; and,
forming a complementary metal-oxide-semiconductor field-effect (CMOSFET) thin-film transistor (TFT) structure in each active semiconductor film section, where the TFT threshold voltage standard deviation for TFTs in the first portion is less TFTs in the second portion, by 60% for n-channel and 30% for p-channel TFTs.

4. The method of claim 1 wherein supplying the wafer with the laser-crystallized active semiconductor film includes supplying the wafer top surface-having a first sheet resistance; and,
wherein forming the top surface with the second roughness includes forming the top surface with a second sheet resistance, less than the first sheet resistance.

5. The method of claim 1 wherein supplying the wafer with the laser-crystallized active semiconductor film includes supplying the wafer top surface having a first interface trap density; and,
wherein forming the top surface with the second roughness includes forming the top surface with a second interface trap density, less than the first interface trap density.

6. The method of claim 1 wherein supplying the wafer with a laser-crystallized active semiconductor film includes supplying an active semiconductor film having a thickness of about 50 nanometers (nm);
wherein laser annealing the active semiconductor film includes using a laser having;
a wavelength of 308 nanometers (nm);
a repetition rate of about 200 Hz;
a total energy pulse energy of about 210 milliJoules per centimeter square (mJ/cm²); and,
a beam shape of 1 mm×10 mm.

7. The method of claim 6 wherein laser annealing the active semiconductor film includes;
scanning the active semiconductor film with a plurality of laser shots in a first direction; and,
scanning the active semiconductor film with a plurality of shots in a second direction, orthogonal to the first direction.

8. The method of claims 7 wherein the scanning in the first direction includes irradiates each point on the active semiconductor top surface with a first number of shots in a range of about 10 to 50; and,
wherein, the scanning in the second direction includes irradiates each point on the active semiconductor top surface with the first number of shots.

9. The method of claim 1 wherein supplying the wafer with a laser-crystallized active semiconductor film includes supplying an active semiconductor film with a first thickness; and,
wherein, melting the top surface of the active semiconductor film, in response to the laser annealing includes melting about the top 30% of the active semiconductor film.

10. The method of claim 1 wherein supplying the wafer with the laser-crystallized, active semiconductor film includes supplying a wafer made from a material selected from a group consisting of Si, Ge, and SiGe.

11. A laser-smoothed, active semiconductor film wafer comprising:
a wafer with a laser-crystallized active semiconductor film having a top surface with a laser-smoothed first portion and a non-laser-smoothed second portion; and,
wherein the first portion top surface has a first sheet resistance; and,
wherein the second portion top surface has a second sheet resistance, greater than the first sheet resistance.

12. The wafer of claim 11 wherein the first portion top surface has a first interface trap density; and,
wherein the second portion top surface has a second interface trap density, greater than the first interface trap density.

13. The method of claim 11 wherein the laser-crystallized active semiconductor film is a material selected from a group consisting of Si, Ge, and SiGe.

14. A complementary metal-oxide-semiconductor field-effect (CMOSFET) thin-film transistor (TFT) array comprising:
a laser-crystallized active semiconductor film having a top surface with a laser-smoothed first portion and a non-laser-smoothed second portion; and,
a first group of TFTs formed in the first portion top surface;
a second group of TFTs formed in a second portion top surface; and,
wherein the TFT threshold voltage standard deviation for TFTs in the first portion is less the TFTs in the second portion, by 60% for n-channel and 30% for p-channel TFTs.

15. The TFT array of claim 14 wherein the laser-crystallized active semiconductor film is a material selected from a group consisting of Si, Ge, and SiGe.
